(19) United States
(12) Patent Application Publication
(10) Pub. No.: US 2008/0278156 A1
(43) Pub. Date: Nov. 13, 2008

(54) Sensor Device With Generator and Sensor Current Sources

(75) Inventors: Bart Michiel De Boer, Den Bosch (NL); Theodorus Petrus Henricus Gerardus Jansen, Deurne (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 12/067,316

(22) PCT Filed: Sep. 12, 2006
(86) PCT No.: PCT/IB06/53226

§ 371 Date: Mar. 19, 2008

(30) Foreign Application Priority Data
Sep. 22, 2005 (EP) 05108743.5

(51) Int. Cl. G01R 33/00

(52) U.S. Cl. 324/234

(57) ABSTRACT

The invention relates to a magnetic sensor device (10) comprising wires (11, 13) for the generation of a magnetic field and a magnetic sensor element (12), for example a GMR (12), for sensing changes of the generated magnetic field caused by magnetic particles (2). The wires (11, 13) and the magnetic sensor element (12) are supplied with alternating currents (I1, I2) of high frequencies f1 and f2. Said frequencies are chosen such that their difference Δf=æf2−f1æ is low and lies in a range of thermal white noise above the 1/f noise of an amplifier (24) and below the 1/f noise of the GMR (12). In this way it is possible to use a high-frequency magnetic field while only low frequency signals have to be processed.

The invention relates to a magnetic sensor device comprising at least one magnetic field generator and at least one associated magnetic sensor element together with associated current supply units. Moreover, the invention relates to the use of such a magnetic sensor device and a method for the detection of at least one magnetic particle with such a magnetic sensor device.

From the WO 2005/010543 A1 and WO 2005/010542 A2 (which are incorporated into the present application by reference) a microsensor device is known which may for example be used in a Microfluidic biosensor for the detection of molecules, e.g. biological molecules, labeled with magnetic beads. The microsensor device is provided with an array of sensors comprising wires for the generation of an alternating magnetic field of a first frequency f₁ and Giant Magneto Resistances (GMR) for the detection of stray fields generated by magnetized beads. The signal of the GMRs is then indicative of the number of the beads near the sensor.

It is known to use a high frequency f₁ for the generated magnetic fields such that the magnetic signal appears in the spectrum at a frequency where not the 1/f noise but the thermal white noise is dominant in the voltage of the GMR. The 1/f noise is the result of the noise resistance spectral density (NRSD) of the GMR, which has a magnetic origin and a 1/f character, multiplied by the sensor current which is applied to the GMR (usually a DC current).

It is further known that a strong crosstalk signal at the bead excitation frequency f₁ appears at the GMR sensor output due to parasitic capacitance and inductive coupling between the current wires and the GMR. This signal interferes with the magnetic signal from the beads. The crosstalk between field generating means and the GMR sensors can be suppressed by modulating the sense current of the GMR sensor with a frequency f₂. The introduction of a modulation of the sensor current has the effect that a magnetic signal does not appear at frequency f₁ (which is overlapped by crosstalk), but at the frequencies f₁±f₂ (which are free of crosstalk).

In the known magnetic sensor devices a high frequency of typically more than 100 kHz is chosen for f₁ and a low frequency of typically 1 kHz for f₂. By modulating the sensor current l₂ with f₂, the noise voltage Uₙₒᵢₛₑ which is caused by the 1/f resistance noise Rₙₒᵢₛₑ is shifted in the spectrum according to the relation Uₙₒᵢₛₑ=I₂ Rₙₒᵢₛₑ. This shift is however small due to the low frequency f₂ of the sensor current. As f₂ is small compared to f₁, the magnetic signals at f₁±f₂ remain in a range of high frequency where thermal white noise dominates. A problem of this approach is however that the involved high frequencies of typically 1 to 500 MHz or possibly even higher are difficult to process. The amplification factor has for example to be large due to the extremely small amplitude of the magnetic signal (which is in the order of 1 μV), and this is difficult to realize in the domain of high frequencies.

Based on this situation it was an object of the present invention to provide means for the detection of magnetic signals with a magnetic sensor device of the kind described above, the means providing a good signal-to-noise ratio (SNR) while being simple to realize in spite of the use of a high frequency magnetic field.

This object is achieved by a magnetic sensor device according to claim 1, a use according to claim 10, and a method according to claim 11. Preferred embodiments are disclosed in the dependent claims.

A magnetic sensor device according to the present invention comprises the following components:
At least one magnetic field generator for generating a magnetic field in an adjacent investigation region. The magnetic field generator may for example be realized by a wire on a substrate of a microsensor.
At least one magnetic sensor element that is associated with the aforementioned magnetic field generator in the sense that it is in the reach of effects caused by the magnetic field of the magnetic field generator. The magnetic sensor element may particularly be a magneto-resistive element of the kind described in the WO 2005/010543 A1 or WO 2005/010542 A2, especially a GMR, a TMR (Tunnel Magneto Resistance), or an AMR (Anisotropic Magneto Resistance).
A generator supply unit for providing an alternating generator current of a first frequency f₁ to the magnetic field generator.
A sensor supply unit for providing an alternating sensor current of a second frequency f₂ to the magnetic sensor element.

Moreover, the absolute difference Δf between the second and the first frequency, i.e. Δf=|f₂−f₁|, is required to fulfill the following conditions:
a) Δf is smaller than both the first frequency f₁ and the second frequency f₂, i.e. Δf≦min(f₁, f₂); and
b) Δf lies in a frequency range where thermal white noise of the magnetic sensor element dominates over the 1/f noise of the magnetic sensor element that is associated with the sensor current.

In the described magnetic sensor device, the desired magnetic signal of the magnetic sensor element can be observed at the frequency difference Δf, where it is free of capacitive crosstalk having frequency f, and where it is in a range of thermal white noise and thus not corrupted by 1/f noise. Moreover, the frequency difference Δf is smaller than both f₁ and f₂, allowing to choose it at relatively low frequencies which are easier to process.

According to a preferred embodiment of the invention, the frequency difference Δf is smaller than 50% of the smallest frequency of f₁ and f₂ (i.e. Δf≦0.5 min(f₁, f₂)), preferably smaller than 10% of the smallest frequency of f₁ and f₂ (i.e. Δf≦0.1 min(f₁, f₂)). With other words, the first and second frequencies f₁, f₂ are chosen comparatively close to each other.

Preferred values for the first frequency f, range from 100 kHz to 10 MHz. Preferred values for the frequency difference Δf range from 10 kHz to 100 kHz. Thus it is possible to use high frequencies f, of the magnetic field, while the magnetic signal is at the same time at comparatively low frequencies Δf, which are easier to process. The invention is however not limited to the stated values but covers also the application of higher frequencies, e.g. up to 10 GHz and more.

According to a further development of the invention, the magnetic sensor device comprises a low pass filter for filtering the signal of the magnetic sensor element with a corner frequency that is smaller than the first frequency f₁. Thus components of the signal with the first frequency f, are excluded from further processing, which is advantageous as disturbances due to crosstalk have that first frequency f₁, too. Preferably, the corner frequency of the low pass filter is just above the frequency difference Δf to let primarily only the magnetic signal pass.

According to another embodiment, the magnetic sensor device comprises an amplifier that is connected to the magnetic sensor element for amplifying its signals. A corruption of the amplified signal by additional 1/f noise of the amplifier is then avoided if the frequency difference Δf lies in a frequency range where the thermal white noise of the amplifier dominates over its 1/f noise.

In another optional embodiment of the magnetic sensor device, the generator supply unit comprises a control input by which different first frequencies f, can be selected.

Similarly, the sensor supply unit may comprise a control input by which different second frequencies f₂ can be selected.

Moreover, both the generator supply unit and the sensor supply unit may be designed in such a way that the first frequency f, and the second frequency f₂ can both be changed synchronically. This means that f₁ and f₂ change while their difference Δf is kept constant.

With a change of the first frequency f₁ of the magnetic field according to one of the aforementioned embodiments, the conditions for the detection of magnetic components like magnetic beads in a biological sample can be changed. In this way it is inter alia possible to discriminate between different beads, for example beads of different size that are attached to different label molecules. The same sensor hardware can thus be used for different screening targets.

The invention further relates to the use of the magnetic sensor device described above for molecular diagnostics, biological sample analysis, or chemical sample analysis. Molecular diagnostics may for example be accomplished with the help of magnetic beads that are directly or indirectly attached to target molecules.

Moreover, the invention relates to a method for the detection of at least one magnetic particle, for example a magnetic bead attached to a label molecule, the method comprising the following steps:
Generating an alternating magnetic field of a first frequency f₁ in the vicinity of a magnetic sensor element.
Operating the magnetic sensor element at a second frequency f₂ and sensing a magnetic property of the magnetic particle that is related to the generated field.
Moreover, the absolute difference Δf between the second and the first frequency, Δf=|f₂−f₁|, shall fulfill the following conditions:
a) Δf is smaller than both the first frequency f, and the second frequency f₂, i.e. Δf≦min(f₁, f₂); and
b) Δf lies in a frequency range where thermal white noise of the magnetic sensor element dominates over the 1/f noise of the magnetic sensor element.

The method comprises in general form the steps that can be executed with a magnetic sensor device of the kind described above. Therefore, reference is made to the preceding description for more information on the details, advantages and improvements of that method.

These and other aspects of the invention will be apparent from and elucidated with reference to the examples described hereinafter. These examples will be described by way of example with the help of the accompanying drawings in which:

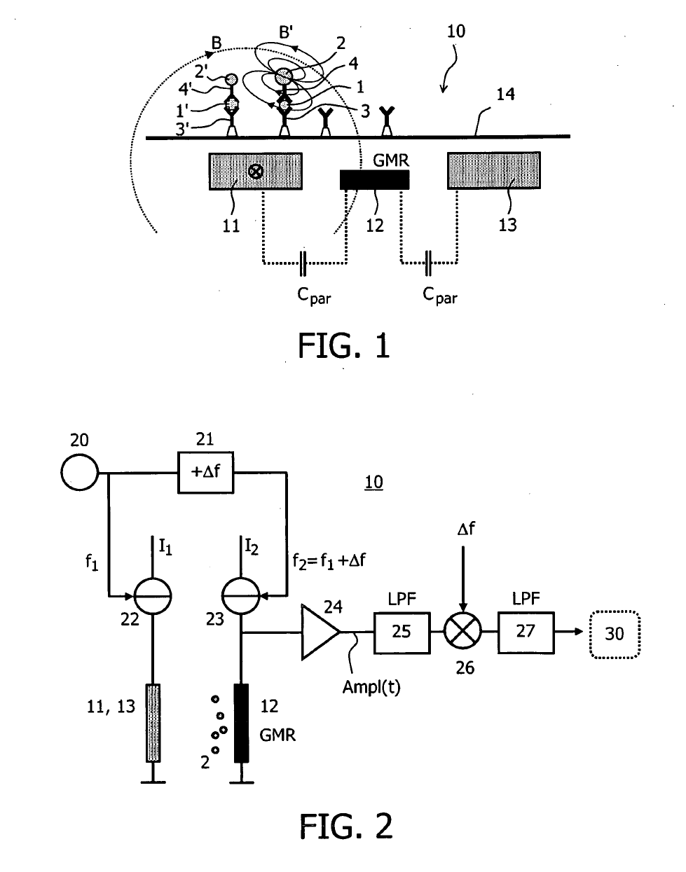

FIG. 1 illustrates the principle of a biosensor with a magnetic sensor device according to the present invention;

FIG. 2 depicts a block diagram of the circuitry of a magnetic sensor device according to the present invention;

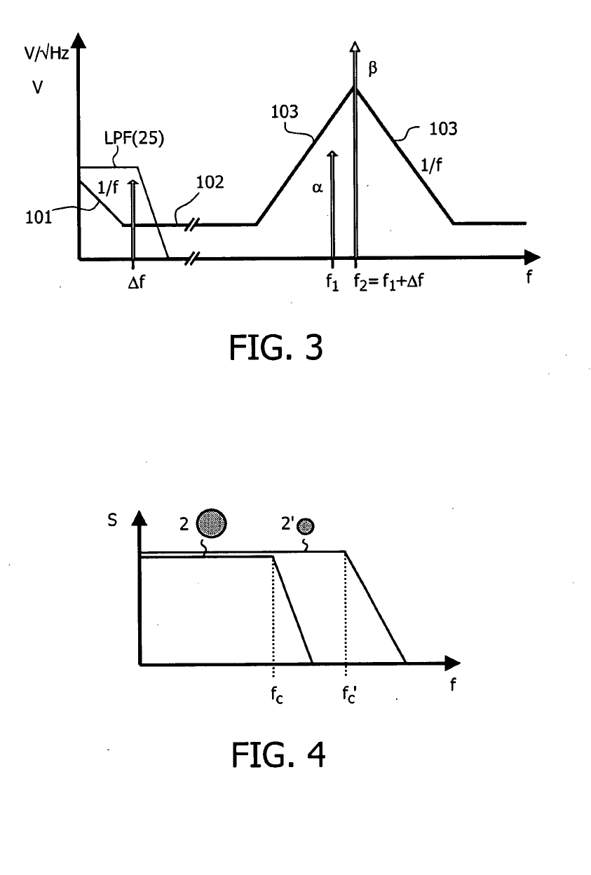

FIG. 3 illustrates the voltage spectrum of the magnetic sensor element of FIG. 2;

FIG. 4 illustrates the frequency response of two beads of different size.

Like reference numbers in the Figures refer to identical or similar components.

FIG. 1 illustrates the principle of a single sensor 10 for the detection of superparamagnetic beads 2, 2′. A biosensor consisting of an array of (e.g. 100) such sensors 10 may be used to simultaneously measure the concentration of a large number of different target molecules 1, 1′ (e.g. protein, DNA, amino acids, drugs of abuse) in a solution (e.g. blood or saliva). In one possible example of a binding scheme, the so-called “sandwich assay”, this is achieved by providing a binding surface 14 with first antibodies 3, 3′ to which the target molecules 1, 1′ may bind. Superparamagnetic beads 2, 2′ carrying second antibodies 4, 4′ may then attach to the bound target molecules 1, 1′. A current flowing in the wires 11 and 13 of the sensor 10 generates a magnetic field B, which then magnetizes the superparamagnetic beads 2, 2′. The stray field B′ from the superparamagnetic beads 2, 2′ introduces an in-plane magnetization component in the GMR 12 of the sensor 10, which results in a measurable resistance change.

As shown in FIG. 1, beads 2, 2′ of different properties (e.g. of different size) may be bound via molecules 4, 4′ to different target molecules 1, 1′ that are linked to the same or different receptors 3, 3′ on the surface 14 of the sensor device.

FIG. 1 further illustrates by dashed lines and capacitors a parasitic capacitive coupling between the current wires 11, 13 and the GMR 12 (similarly an inductive coupling is present between these components, too). This coupling produces a crosstalk in the signal voltage of the GMR 12, wherein the crosstalk occurs at the frequency f₁ of the field generating current I₁ in the wires 11, 13. As will be explained in more detail below, disturbances by this crosstalk can be minimized if the sensor current I₂ flowing through the GMR 12 is also modulated with a second frequency f₂.

FIG. 2 shows the schematic block diagram of a circuitry that can be used in connection with the magnetic sensor device 10 of FIG. 1. Said circuitry comprises a current source or “generator supply unit” 22 that is coupled to the conductor wires 11, 13 to provide them with a generator current I₁. Similarly, the GMR 12 is coupled to a second current source or “sensor supply unit” 23 that provides the GMR 12 with a sensor current I₂. The signal of the GMR 12, i.e. the voltage drop across its resistance, is sent via an amplifier 24, a first low pass filter 25, a demodulator 26, and a second low pass filter 27 to the output 30 of the sensor device for final processing (e.g. by a personal computer).

The generator current I₁ is modulated with a first frequency f₁ that is generated by a modulation source 20. The signal of said modulation source 20 is further sent via a frequency shifter 21 to the second sensor current source 23 to modulate the sensor current I₂ with the second frequency f₂=f₁+Δf. Assuming the modulation signal to be a sinusoidal wave, the generator and the sensor currents become:

I₁=I_{1,0} sin(2πf₁t),

I₂=I_{2,0} sin(2πf₂t).

The high frequency current I₁ in the wires 11, 13 induces a magnetic field in the GMR 12. Because of the fact that the GMR sensor is exclusively sensitive to magnetic fields, only the magnetic component (and not parasitic capacitive crosstalk) of the measurement signal of the sensor 12 is multiplied by the sensor current I₂. After amplification in the amplifier 24, the amplified signal Ampl(t) therefore becomes:

$$\begin{matrix}Ampl ( t ) = μ N [ {I}_{1 , 0} sin ( 2 π {f}_{1} t ) ] [ {I}_{2 , 0} sin ( 2 π {f}_{2} t ) ] + α {I}_{1 , 0} sin ( 2 π {f}_{1} t ) + \\ β {I}_{2 , 0} sin ( 2 π {f}_{2} t ) \\ = 1 / 2 μ {NI}_{1 , 0} {I}_{2 , 0} [ cos 2 πΔ f t - {cos}^{2} π ( {f}_{1} + {f}_{2} ) t ] + \\ α {I}_{1 , 0} sin ( 2 π {f}_{1} t ) + β {I}_{2 , 0} sin ( 2 π {f}_{2} t ) ,\end{matrix}$$

wherein N is the number of magnetic beads 2 in the vicinity of the GMR 12, μ is a proportionality factor, α is a constant related to the capacitive and inductive crosstalk between the wires 11, 13 and the GMR 12, and β is a constant related to the sensor voltage induced by the sensor current I₂ in the GMR 12.

FIG. 3 schematically shows the spectrum of the voltage output of the amplifier 24 and its noise voltage spectral density (lines 101, 102, 103). The discussed signal Ampl(t) contributes to this spectrum with a signal component at Δf, with a crosstalk related component (a term) at f₁, with a sensor current related component (β term) at f₂, and with a component at f₁+f₂ (not shown). The diagram further shows a first region 101 of 1/f noise generated by the amplifier 24, and a second region 103 of 1/f noise due to the noise resistance spectral density (nRSD) of the GMR 12, wherein the second region 103 is centered at the sensor frequency f₂. Between the two regions 101, 103 of 1/f noise lies a region 102 where thermal white noise dominates.

Based on this situation, the first frequency f₁ of the generator current and the second frequency f₂ of the sensor current have been chosen such that both of them are relatively high (e.g. in the order of 1 MHz) while their difference Δf is low (e.g. in the order of 50 kHz). A preferred choice of frequencies is such that the magnetic signal at Δf, which is proportional to the desired number N of beads, occurs just above the region 101, i.e. in region 102 where thermal white noise is the dominant noise source in the amplifier. In this way, the highest possible signal-to-noise ratio with the lowest possible (and thus easy to process) magnetic signal frequency Δf has been achieved.

FIG. 3 further shows the characteristic LPF (25) of the low pass filter 25 that is arranged behind the amplifier 24 in the block diagram of FIG. 2. The corner frequency of this low pass filter 25 shall be just above Δf. The low pass filter 25 provides a simple means to eliminate capacitive and inducted crosstalk occurring at the high frequencies f₁ and f₂, and noise.

Referring again to FIG. 2, it can be further seen that a demodulator 26 is arranged behind the low pass filter 25. In the demodulator 26, the filtered signal is multiplied with a signal of frequency Δf (for example a signal cos 2π(Δf t)). The output of the demodulator 26 then comprises a DC component proportional to N, i.e. the desired biological value. A further low pass filter 27 can be applied to this output, wherein the corner frequency of that filter 27 should correspond to the bandwidth of the biological signal (i.e. the time variation of N), which is typically in the order of 1 Hz.

A particular advantage of the described magnetic sensor device is that the field and sense current frequencies f₁, f₂ may be changed at any time, provided that the difference Δf in frequency is constant. This allows for a “scanning” in the frequency domain to obtain a frequency response of the system with beads. Such a change in frequency does not affect the complexity of the low pass filter: the crosstalk component will increase with frequency, but the suppression of the filter also increases by the same amount (or more depending on the order of the filter) with frequency. The sense current component, which is independent of frequency, will only be suppressed more for higher sense current frequencies.

The high field frequencies f, (e.g. in the range of 1 to 500 MHz, possibly even higher) that can be used are especially important if beads shall be multiplexed during measurements: As shown in FIG. 1, different beads 2, 2′ may be attached to different analytes (target molecules) via selective antibodies in a sandwich assay. This allows for the measurement of the concentrations of multiple analytes at the same time with the same sensor: by using different field frequencies f₁ one can distinguish between the different types of beads, and thus the concentrations of different analytes. Small beads will for example still respond to a field with a high frequency while large beads will not be able to follow the field. Different sized beads (or differently manufactured beads) thus have different relaxation times and will have different cut-off frequencies in their field frequency response.

FIG. 4 depicts schematically the frequency response of two beads 2, 2′ of different size. By using the frequency f₁=f_{c}′ for the field, a signal of only the small beads 2′ is obtained, without interference of the larger beads. The cut-off frequencies f_{c}, f_{c}′ can be in the order of several hundreds of MHz.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. A magnetic sensor device (10) comprising
at least one magnetic field generator (11, 13);
at least one associated magnetic sensor element (12);
a generator supply unit (22) for providing an alternating generator current (I₁) of a first frequency f₁ to the magnetic field generator (11, 13);
a sensor supply unit (23) for providing an alternating sensor current (I₂) of a second frequency f₂ to the magnetic sensor element (12);
wherein the difference between the second and the first frequency, [symbol] =|f₂−f₁|, fulfills the following conditions:
a) said difference [symbol] is smaller than both the first frequency f₁ and the second frequency f₂, [symbol] } min(f₁, f₂), and
b) said difference [symbol] lies in a frequency range (102) where the thermal white noise of the magnetic sensor element (12) dominates over 1/f noise (103) of the magnetic sensor element (12) that is associated with the sensor current (I₂).

2. The magnetic sensor device (10) according to claim 1, characterized in that the frequency difference f is smaller than 0.5 min(f₁, f₂), preferably smaller than 0.1 min(f₁, f₂).

3. The magnetic sensor device (10) according to claim 1, characterized in that the first frequency f₁ ranges from 100 kHz to 10 MHz.

4. The magnetic sensor device (10) according to claim 1, characterized in that the frequency difference f ranges from 10 kHz to 100 kHz.

5. The magnetic sensor device (10) according to claim 1, characterized in that it comprises a low pass filter (25) for filtering the signal of the magnetic sensor element (12) with a corner frequency smaller than the first frequency f₁ and larger than the frequency difference [symbol] .

6. The magnetic sensor device (10) according to claim 1, characterized in that it comprises an amplifier (24) for amplifying the signal of the magnetic sensor element (12), wherein the frequency difference flies in a frequency range (102) where thermal white noise dominates over 1/f noise (101) of the amplifier.

7. The magnetic sensor device (10) according to claim 1, characterized in that the generator supply unit (22) comprises a control input via which different first frequencies f₁ can be selected.

8. The magnetic sensor device (10) according to claim 1, characterized in that the sensor supply unit (23) comprises a control input via which different second frequencies f₂ can be selected.

9. The magnetic sensor device (10) according to claim 1, characterized in that it is designed such that the first frequency f₁ and the second frequency f₂ can be changed synchronically while keeping their difference f constant.

10. Use of the magnetic sensor device (10) according to claim 1 for molecular diagnostics, biological sample analysis, or chemical sample analysis.

11. A method for the detection of at least one magnetic particle (2, 2′), comprising the following steps:
generating an alternating magnetic field (B) of a first frequency f₁ in the vicinity of a magnetic sensor element (12);
operating the magnetic sensor element (12) at a second frequency f₂ and sensing a magnetic property of the magnetic particle (2, 2′) that is related to the generated magnetic field (B),
wherein the difference between the second and the first frequency, [symbol] =|f₂−f₁|, fulfills the following conditions:
a) said difference [symbol] is smaller than both the first frequency f₁ and the second frequency f₂, [symbol] } min(f₁, f₂), and
b) said difference [symbol] lies in a frequency range (102) where the thermal white noise of the magnetic sensor element (12) dominates over 1/f noise (103) of the magnetic sensor element (12).
